(19) United States
(12) Patent Application Publication
(10) Pub. No.: US 2012/0119789 A1
(43) Pub. Date: May 17, 2012

(54) Peak Detector Extension System

(75) Inventors: Gabriel Leandro Romero, Colorado Springs, CO (US); Coralyn S. Gauvin, Manitou Springs, CO (US)

(73) Assignee: LSI CORPORATION, Milpitas, CA (US)

(21) Appl. No.: 12/947,056

(22) Filed: Nov. 16, 2010

(51) Int. Cl. H03K 5/153

(52) U.S. Cl. 327/58

(57) ABSTRACT

The different illustrative embodiments provide a method and apparatus for managing peak detector circuits. A first number of voltages for a first number of signals detected by a peak detector circuit connected to a wire in a bus system is identified. The first number of signals is used to send data over the wire. The first number of voltages is for a first number of transmission speeds for the first number of signals. A second number of voltages for a second number of signals detected by the peak detector circuit is identified. The second number of signals is present in the wire in an absence of the data being sent over the wire. The second number of voltages is for a second number of transmission speeds for the second number of signals. A number of settings are selected for the peak detector circuit based on the first number of voltages and the second number of voltages.

### BACKGROUND OF THE INVENTION

1. Technical Field

The present invention is directed generally to buses and data processing systems and, in particular, to serial buses. Still more particularly, the present disclosure relates to a method and apparatus for extending the range of peak detectors used in Out of Band signaling with serial buses.

2. Description of the Related Art

A bus is a system used to transfer data between different components. Buses are typically used in computers and components, such as hard disk drives. One type of bus is a serial bus. A serial bus transmits data one bit at a time over a wire. This wire also may be referred to as a channel on the bus.

With serial buses, data is often transferred over a speed or range of speeds. When signals are transmitted outside of this speed or range of speeds, this type of signaling is often referred to as Out of Band signaling. Out of Band signaling may be used to establish connections or reinitialize links between components. Out of Band signaling may involve sending data in groups or bursts. This data is sent at a speed that is low with respect to the speed used to send data during data transfers between components. With Out of Band signaling in serial buses, the negotiation times may be long and may convey information in a manner such that the phase lock loops in the serializer and deserializer components do not lock on to this type of signaling. In this manner, a signal may be sent and received on the same wires that are later used to exchange data at higher speeds. Typically, Out of Band data contains information on the speed or protocol that will be supported between the components. Further, this type of signaling also may be used to reset a link or wake a device that has been put into a lower power state. For example, a serializer and deserializer used in transmitting data between components may move into a sleep state. This state is a lower power state that is used to conserve power.

Currently, running a component configured for higher speeds, such as a serializer and deserializer (SerDes), at lower speeds used for Out of Band signaling may pose problems. These types of devices do not run as well at the speeds used for Out of Band signaling. As one illustrative example, this issue becomes more evident when using a serializer and deserializer designed to operate at a speed of 12 gigabytes per second (GB/s) and operating the device at a speed of 1.5 gigabytes per second for Out of Band signals.

Therefore, it would be advantageous to have a method and apparatus that takes into account or more of the issues discussed above, as well as possibly other issues.

### SUMMARY OF THE INVENTION

The different illustrative embodiments provide a method and apparatus for managing peak detector circuits. A first number of voltages for a first number of signals detected by a peak detector circuit connected to a wire in a bus system is identified. The first number of signals is used to send data over the wire. The first number of voltages is for a first number of transmission speeds for the first number of signals. A second number of voltages for a second number of signals detected by the peak detector circuit is identified. The second number of signals is present in the wire in an absence of the data being sent over the wire. The second number of voltages is for a second number of transmission speeds for the second number of signals. A number of settings are selected for the peak detector circuit based on the first number of voltages and the second number of voltages.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of an illustrative embodiment when read in conjunction with the accompanying drawings, wherein:

FIG. 1 is an illustration of a data transmission environment in accordance with an illustrative embodiment;

FIG. 2 is an illustration of a data transmission environment in accordance with an illustrative embodiment;

FIG. 3 is an illustration of a flowchart of a process for managing peak detector circuits in accordance with an illustrative embodiment;

FIG. 4 is an illustration of a flowchart of a process for managing a peak detector circuit in accordance with an illustrative embodiment;

FIG. 5 is an illustration of a flowchart of a process for managing a peak detector circuit in accordance with an illustrative embodiment; and

FIG. 6 is an illustration of a flowchart of a process for managing a training process in accordance with an illustrative embodiment.

### DETAILED DESCRIPTION

The illustrative embodiments recognize and take into account a number of different considerations. For example, the illustrative embodiments recognize and take into account that the detection of Out of Band signals may be performed using components other than those normally used to transfer data. For example, a circuit in the form of an Out of Band detector may be used independently from a serializer and deserializer used to transfer data. The different illustrative embodiments recognize and take into account that an Out of Band detector may be a comparator with an internal reference. The internal reference may be adjusted to change the voltage level at which the detector detects the presence or absence of signal.

The different illustrative embodiments recognize and take into account that simplifying data patterns and repeating the sending of bits in data patterns may not provide a desired solution when a serializer and deserializer is in a sleep state. As one illustrative example, a serializer and deserializer goes into a sleep state operating at a speed of 12 gigabytes per second. The Out Of Band signaling that is used to wake up the serializer and deserializer may be a previously negotiated rate. For example, the previously negotiated rate may be about 12 gigabytes per second and not the normal rate of 1.5 gigabytes per second. The different illustrative embodiments recognize and take into account that the detectors for Out of Band signaling currently used may not be able to detect the Out of Band signaling at these higher speeds.

The different illustrative embodiments recognize and take into account that the frequency content within the Out of Band signal may be different, depending on the state of the device entering a lower power state. The different illustrative embodiments recognize and take into account that timing requirements may be used to leave the low power state and resume normal operations. These types of timing requirements may require Out of Band detectors to provide outputs that are accurate enough such that timers may be started to ensure compliance with these requirements.

For example, a device leaving a low power state may be required to leave the state at a particular time and follow a set of timed sequences in leaving the state. These sequences may be timed from the point at which an Out of Band sequence is received. For example, as the frequency of the burst within the Out of Band signal increases, the attenuation seen in the signal over the wire also increases. For example, a difference in amplitude between a 750 megahertz signal and a 3 gigahertz signal may be about 9 dB. As a result, the same Out of Band signal presented during the initial startup may have a 1.2V differential. But, the Out of Band signal, when coming out of a low power state, may have a 300 mV differential. With noise over the wire, the difference between the two signals may only be about 150 mV.

In other words, as the speed or frequency goes up, a detector for detecting Out of Band signals may have more difficulty in identifying the difference between a logic 0 and a logic 1. As a result, the ability to detect whether a signal is present on a wire may be decreased as the speed of data increases.

The different illustrative embodiments recognize and take into account that currently used detectors are not designed to take into account the attenuation in signals during different speeds. Thus, the different illustrative embodiments recognize and take into account that it may be advantageous to determine settings for a detector used to detect Out of Band signals for each particular wire that a detector is associated with. Further, this selection of settings may be based on expected or axle speeds that are used over the wire.

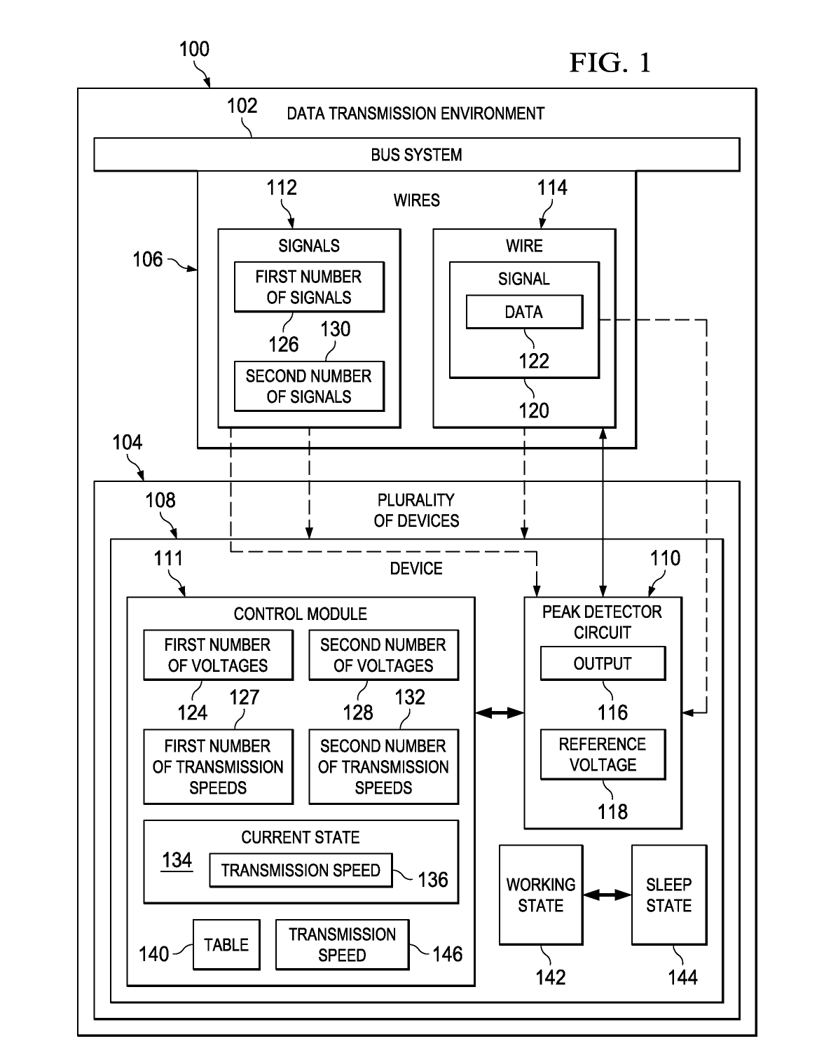

With reference now to FIG. 1, an illustration of a data transmission environment is depicted in accordance with an illustrative embodiment. Data transmission environment 100 is an example of an environment in which the different illustrative embodiments may be implemented. In these illustrative examples, data transmission environment 100 comprises bus system 102 and plurality of devices 104. Plurality of devices 104 is connected to bus system 102 using wires 106. Wires 106 allow plurality of devices 104 to communicate with each other using bus system 102.

As depicted, device 108 is an example of a device in plurality of devices 104. Device 108 may be, for example, without limitation, an initiator device, a hard disk drive, a solid state drive, an encloser device, a Serial Attached Small Computer Interface System (SAS, Serial Attached SCSI) controller, and/or some other suitable type of device.

In these illustrative examples, device 108 comprises peak detector circuit 110 and control module 111. In these depicted examples, peak detector circuit 110 is configured to detect signals 112 being sent over wire 114 in wires 106 connected to bus system 102. Signals 112 are Out of Band signals in these examples. Peak detector circuit 110 generates output 116 indicating whether a signal in signals 112 that is detected by peak detector circuit 110 is carrying data. For example, output 116 may have one value indicating the presence of data in the signal and another value indicating the absence of the data in the signal.

Output 116 is generated by peak detector circuit 110 using reference voltage 118 for peak detector circuit 110. As one illustrative example, when signal 120 in wire 114 detected by peak detector circuit 110 has a voltage that is greater than reference voltage 118, peak detector circuit 110 generates output 116 indicating the presence of data 122 in signal 120. When signal 120, detected by peak detector circuit 110, has a voltage that is less than reference voltage 118, peak detector circuit 110 generates output 116 indicating the absence of data 122 in signal 120.

Control module 111 is associated with peak detector circuit 110. In these depicted examples, control module 111 may be comprised of hardware components, firmware components, and/or a combination of both. For example, without limitation, control module 111 may be an application-specific integrated circuit (ASIC), a processor unit, and/or some other suitable type of control module.

In these illustrative examples, control module 111 is configured to control the settings for peak detector circuit 110. In particular, control module 111 controls reference voltage 118 for peak detector circuit 110. In these illustrative examples, control module 111 selects reference voltage 118 for peak detector circuit 110 based voltages identified for peak detector circuit 110 during training for peak detector circuit 110. Training for peak detector circuit 110 includes identifying voltages for peak detector circuit 110 that indicate when data is present and/or absent in signals 112 detected by peak detector circuit 110 at different transmission speeds.

For example, control module 111 identifies first number of voltages 124 for first number of signals 126 detected by peak detector circuit 110. A number, as used herein with reference to an item, means one or more items. For example, a number of voltages means one or more voltages.

First number of signals 126 is used to send data over wire 114. When reference voltage 118 for peak detector circuit 110 is set to a voltage in first number of voltages 124, output 116 of peak detector circuit 110 indicates the presence of data being sent over wire 114 using a signal in first number of signals 126. In these illustrative examples, first number of voltages 124 is for first number of transmission speeds 127. In other words, each voltage in first number of voltages 124 corresponds to a transmission speed in first number of transmission speeds 127.

Further, control module 111 identifies second number of voltages 128 for second number of signals 130 detected by peak detector circuit 110. Second number of signals 130 is present in wire 114 in an absence of data being sent over wire 114. In other words, second number of signals 130 is a number of noise signals in wire 114. When reference voltage 118 for peak detector circuit 110 is set to a voltage in second number of voltages 128, output 116 of peak detector circuit 110 indicates an absence of data 122 being sent over wire 114. In these illustrative examples, second number of voltages 128 is for second number of transmission speeds 132. In other words, each voltage in second number of voltages 128 corresponds to a particular transmission speed in second number of transmission speeds 132.

In these illustrative examples, one, some, all, or none of first number of signals 126 may be the same as second number of signals 130. Further, one, some, all, or none of first number of transmission speeds 127 may be the same as second number of transmission speeds 132.

As one illustrative example, control module 111 identifies current state 134 for device 108. Current state 134 comprises transmission speed 136 and an indication of whether data is being sent to device 108. Current state 134 may be one of three states in these illustrative examples. For example, current state 134 may be one of a normal operations state, an Out of Band signaling state, and an off state. In the normal operations state, data is received that is considered to be valid data. In the Out of Band signaling state, Out of Band signals are received. In the off state, no data or signals are received. In this manner, current state 134 indicates that data is being sent to device 108 when current state 134 is a normal operations state.

In this illustrative example, control module 111 determines whether a voltage for current state 134 has been identified in first number of voltages 124 and/or second number of voltages 128. For example, if current state 134 for device 108 indicates that data is being received, control module 111 determines whether a voltage is present in first number of voltages 124 for transmission speed 136. If a voltage is not present in first number of voltages 124 for transmission speed 136, control module 111 identifies the voltage for transmission speed 136 at which output 116 of peak detector circuit 110 indicates the presence of the data being sent over wire 114. For example, control module 111 identifies the voltage that is closest to a highest voltage level for peak detector circuit 110 at which output 116 indicates the presence of data being sent over wire 114. This voltage is selected as a voltage in first number of voltages 124 for transmission speed 136.

Further, if current state 134 for device 108 indicates that data is not being received, control module 111 determines whether a voltage is present in second number of voltages 128 for transmission speed 136. If a voltage is not present in second number of voltages 128 for transmission speed 136, control module 111 identifies the voltage for transmission speed 136 at which output 116 of peak detector circuit 110 indicates an absence of data being sent over wire 114. For example, control module 111 identifies the voltage that is closest to a lowest voltage setting for peak detector circuit 110 at which output 116 indicates an absence of data being sent over wire 114. This voltage is selected as a voltage in second number of voltages 128 for transmission speed 136.

In these illustrative examples, control module 111 stores first number of voltages 124 for first number of transmission speeds 127 and second number of voltages 128 for second number of transmission speeds 132 in table 140. Table 140 relates each voltage in first number of voltages 124 to a transmission speed in first number of transmission speeds 127. Further, table 140 relates each voltage in second number of voltages 128 to a transmission speed in second number of transmission speeds 132.

In some illustrative examples, control module 111 receives a request for device 108 to change from working state 142 to sleep state 144. In response to receiving this request, control module 111 identifies transmission speed 146 for device 108 when device 108 changes back from sleep state 144 to working state 142. Control module 111 then identifies a first voltage in first number of voltages 124 for transmission speed 146 and a second voltage in second number of voltages 128 for transmission speed 146. Control module 111 sets reference voltage 118 for peak detector circuit 110 to a voltage within the range of voltages from the first voltage to the second voltage prior to device 108 changing from working state 142 to sleep state 144. In sleep state 144, noise signals are present in wire 114. By setting reference voltage 118 to a voltage within the range of voltages from the first voltage to the second voltage, peak detector circuit 110 may be able to detect the presence of data at transmission speed 146, while device 108 is in sleep state 144. As one illustrative example, peak detector circuit 110 may be able to detect data 122 that is sent over wire 114 to cause device 108 to wake up from sleep state 144 and enter working state 142 at transmission speed 146.

In these depicted examples, the voltage selected for reference voltage 118 is a voltage that is not the first voltage or the second voltage and is closer to the first voltage. However, in other illustrative examples, the voltage selected for reference voltage 118 may be the first voltage or the second voltage.

In these illustrative examples, if control module 111 does not identify a first voltage in first number of voltages 124 for transmission speed 146 and/or a second voltage in second number of voltages 128 for transmission speed 146, control module 111 may perform a number of operations. For example, without limitation, control module 111 may generate a notification that device 108 cannot enter sleep state 144. In some illustrative examples, control module 111 may generate a notification indicating that some other manner of setting peak detector circuit 110 to detect the presence of data 122 in wire 114 may need to be used.

The illustration of data transmission environment 100 in FIG. 1 is not meant to imply physical or architectural limitations to the manner in which different illustrative embodiments may be implemented. Other components in addition to and/or in place of the ones illustrated may be used. Some components may be unnecessary in some illustrative embodiments. Also, the blocks are presented to illustrate some functional components. One or more of these blocks may be combined and/or divided into different blocks when implemented in different illustrative embodiments.

For example, in some illustrative embodiments, a portion of control module 111 may be located external to or remote to device 108. In other illustrative examples, first number of voltages 124 and second number of voltages 128 may be stored in a data structure other than table 140. For example, without limitation, the voltages may be stored in a database or spreadsheet. In still other illustrative examples, other components in addition to the ones presented for device 108 may be included. For example, device 108 may include a serializer and deserializer.

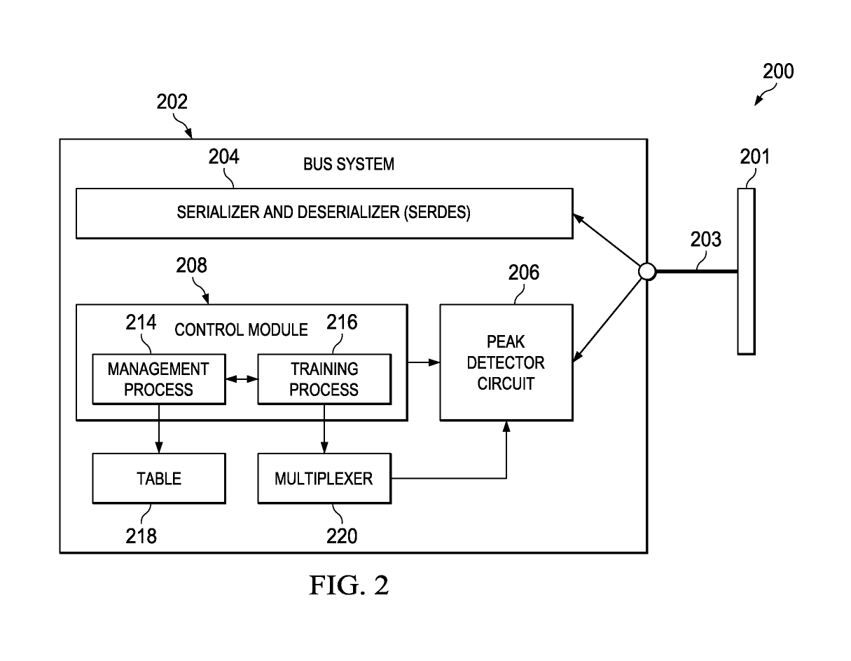

With reference now to FIG. 2, an illustration of a data transmission environment is depicted in accordance with an illustrative embodiment. In this illustrative example, data transmission environment 200 is an example of one implementation for data transmission environment 100 in FIG. 1. As depicted, data transmission environment 200 includes device 201 and bus system 202. Device 201 and bus system 202 are examples of implementations for device 108 and bus system 102, respectively, in FIG. 1. Device 201 is connected to bus system 202 by wire 203. Signals are received at device 201 through wire 203.

In this depicted example, device 201 comprises serializer and deserializer 204, peak detector circuit 206, control module 208, and multiplexer 210. Serializer and deserializer 204 is configured to operate at higher speeds. Serializer and deserializer 204 may not be configured to run at the lower speeds for Out of Band signals. Peak detector circuit 206 is configured to receive Out of Band signals and detect the presence and/or absence of data in these signals.

Multiplexer 210 is configured to set the reference voltage for peak detector circuit 206. Multiplexer 210 may set the reference voltage for peak detector circuit 206 based on a number of registers connected to multiplexer 210 and/or a state machine.

In this illustrative example, control module 208 controls the reference voltage that is set for peak detector circuit 206. Control module 208 comprises management process 214 and training process 216. During operation of device 201, management process 214 identifies a current state for device 201. The current state comprises a transmission speed for device 201 and an indication of whether data is being sent over wire 203. Management process 214 determines whether training has been performed using peak detector circuit 206 for the current state. If training has not been performed, management process 214 sends a command to training process 216.

In response to receiving the command from management process 214, training process 216 overrides multiplexer 210 and causes multiplexer 210 to change the reference voltage for peak detector circuit 206 until the output of peak detector circuit 206 identifies the presence of data in the signal when the current state for device 201 indicates that data is being sent over wire 203. Similarly, training process 216 causes multiplexer 210 to change the reference voltage for peak detector circuit 206 until the output of peak detector circuit 206 identifies an absence of data in the signal when the current state for device 201 indicates that data is not being sent over wire 203. Training process 216 may identify the presence and/or absence of data in the signal based on a policy.

The policy may be, for example, a number of rules and/or guidelines for training using peak detector circuit 206. For example, the policy may indicate that the presence of data is identified when the output of peak detector circuit 206 has a value of “1” for a selected period of time. Further, the policy may indicate that an absence of data is identified when the output of peak detector circuit 206 has a value of “0” for a selected period of time.

Further, training process 216 may change the reference voltage according to the policy. For example, when trying to detect a presence of data, training process 216 may initially set the reference voltage for peak detector circuit 206 to a highest voltage level for peak detector circuit 206. Training process 216 may wait for a period of time identified in the policy before changing the reference voltage another time. Training process 216 may reduce the reference voltage for peak detector circuit 206 until the presence of data is identified using the output of peak detector circuit 206.

Similarly, when trying to detect an absence of data, training process 216 may initially set the reference voltage for peak detector circuit 206 to a lowest voltage level for peak detector circuit 206. Training process 216 may then increase the reference voltage for peak detector circuit 206 until the absence of data is identified using the output of peak detector circuit 206.

In this illustrative example, training process 216 identifies the particular voltage at which the presence and/or absence of data is identified and sends this particular voltage to management process 214. Management process 214 stores this particular voltage in table 218. In particular, management process 214 stores this particular voltage in table 218 with respect to the transmission speed for the current state for device 201.

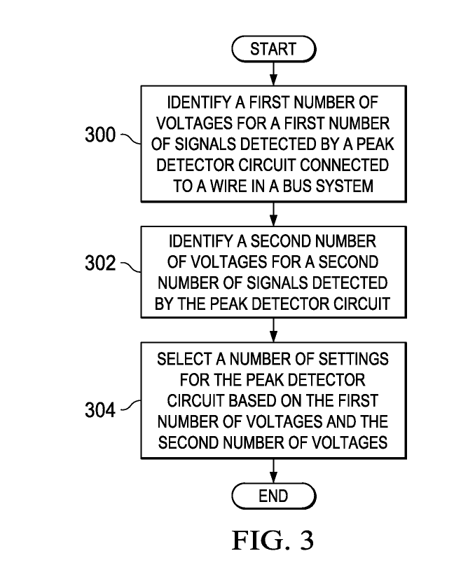

With reference now to FIG. 3, an illustration of a flowchart of a process for managing peak detector circuits is depicted in accordance with an illustrative embodiment. The process illustrated in FIG. 3 may be implemented in data transmission environment 100 in FIG. 1. In particular, the process may be implemented using control module 111 and peak detector circuit 110 in FIG. 1.

The process begins by identifying a first number of voltages for a first number of signals detected by a peak detector circuit connected to a wire in a bus system (operation 300). The first number of signals is used to send data over the wire. Further, the first number of voltages is for a first number of transmission speeds for the first number of signals.

Thereafter, the process identifies a second number of voltages for a second number of signals detected by the peak detector circuit (operation 302). The second number of signals is present in the wire in an absence of the data being sent over the wire. The second number of voltages is for a second number of transmission speeds for the second number of signals.

Next, the process selects a number of settings for the peak detector circuit based on the first number of voltages and the second number of voltages (operation 304), with the process terminating thereafter. In operation 304, the number of settings is a number of reference voltages for the peak detector circuit.

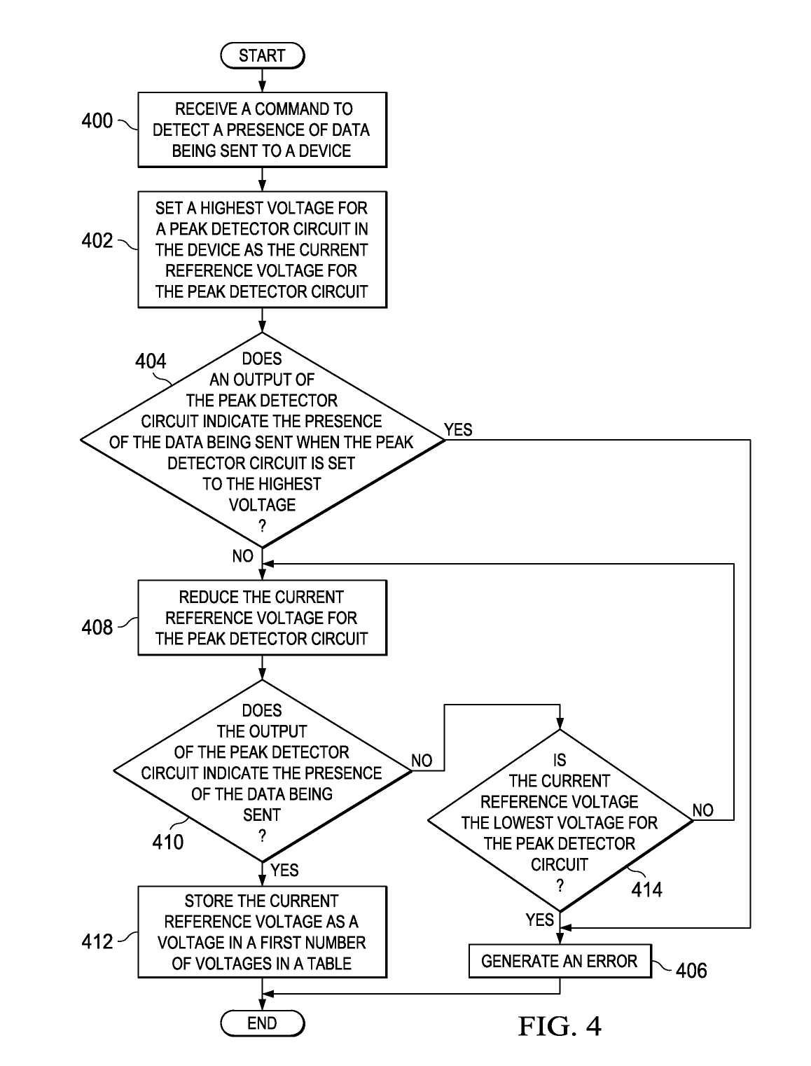

With reference now to FIG. 4, an illustration of a flowchart of a process for managing a peak detector circuit is depicted in accordance with an illustrative embodiment. The process illustrated in FIG. 4 may be implemented in data transmission environment 100 in FIG. 1. In particular, the process may be implemented using training process 216 in control module 208 in FIG. 2.

The process begins by receiving a command to detect a presence of data being sent to a device (operation 400). The device is connected to a bus system through a wire. The data is being sent over the wire. The process sets a highest voltage for a peak detector circuit in the device as the current reference voltage for the peak detector circuit (operation 402).

The process then determines whether an output of the peak detector circuit indicates the presence of the data being sent when the peak detector circuit is set to the highest voltage (operation 404). In operation 404, this determination may be made using the values of the output of the peak detector circuit. For example, the output of the peak detector circuit may have a value of “1” when the presence of data is identified. Further, the output of the peak detector circuit may have a value of “0” when an absence of data is identified.

With reference again to operation 404, if the output of the peak detector circuit indicates the presence of data when the peak detector circuit is set to the highest voltage, the process generates an error (operation 406), with the process terminating thereafter. Otherwise, if the output of the peak detector circuit does not indicate the presence of the data being sent when the peak detector circuit is set to the highest voltage, the process reduces the current reference voltage for the peak detector circuit (operation 408).

Thereafter, the process determines whether the output of the peak detector circuit indicates the presence of the data being sent (operation 410). If the output of the peak detector circuit indicates the presence of data, the process stores the current reference voltage as a voltage in a first number of voltages in a table (operation 412), with the process terminating thereafter. The first number of voltages is, for example, first number of voltages 124 in FIG. 1.

With reference again to operation 410, if the output of the peak detector circuit does not indicate the presence of data, the process determines whether the current reference voltage is a lowest voltage for the peak detector circuit (operation 414). If the current reference voltage is the lowest voltage, the process proceeds to operation 406 as described above. Otherwise, the process proceeds to operation 408 as described above.

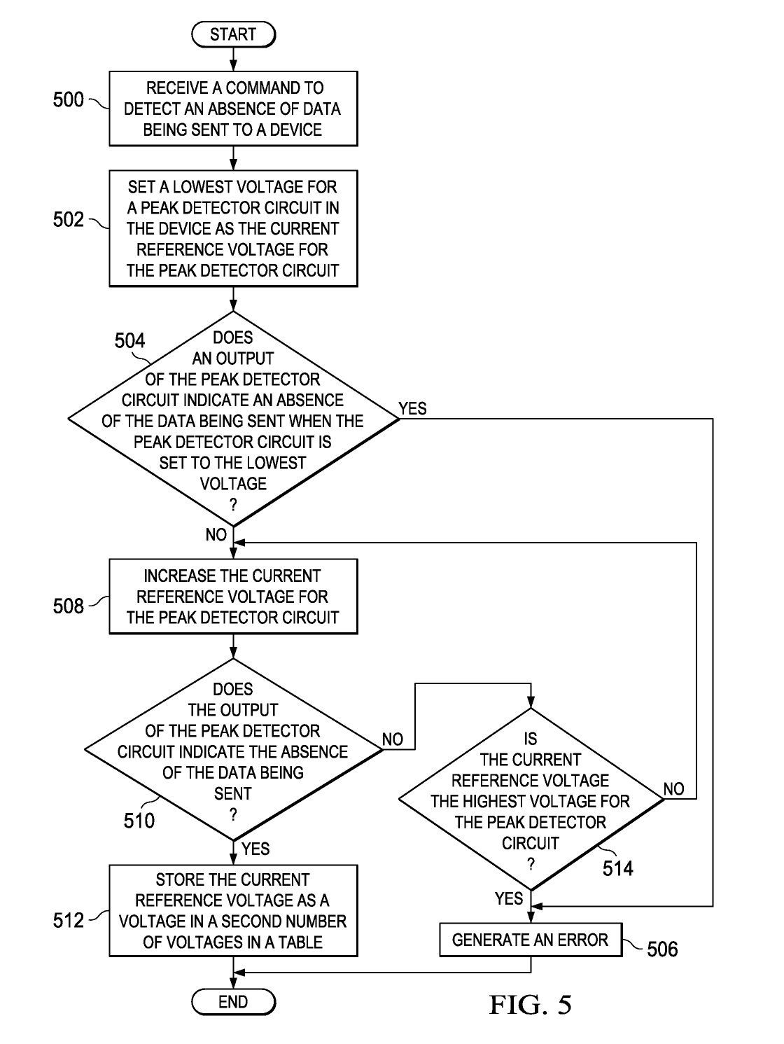

With reference now to FIG. 5, an illustration of a flowchart of a process for managing a peak detector circuit is depicted in accordance with an illustrative embodiment. The process illustrated in FIG. 5 may be implemented in data transmission environment 100 in FIG. 1. In particular, the process may be implemented using training process 216 in control module 208 in data transmission environment 200 in FIG. 2.

The process begins by receiving a command to detect an absence of data being sent to a device (operation 500). The process sets a lowest voltage for a peak detector circuit in the device as the current reference voltage for the peak detector circuit (operation 502). The process then determines whether an output of the peak detector circuit indicates the absence of the data being sent when the peak detector circuit is set to the lowest voltage (operation 504).

In operation 504, this determination may be made using the values of the output of the peak detector circuit. For example, the output of the peak detector circuit may have a value of “1” when the presence of data is identified. Further, the output of the peak detector circuit may have a value of “0” when an absence of data is identified.

With reference again to operation 504, if the output of the peak detector circuit indicates an absence of data when the peak detector circuit is set to the lowest voltage, the process generates an error (operation 506), with the process terminating thereafter. Otherwise, if the output of the peak detector circuit does not indicate an absence of the data being sent when the peak detector circuit is set to the lowest voltage, the process increases the current reference voltage for the peak detector circuit (operation 508).

Thereafter, the process determines whether the output of the peak detector circuit indicates an absence of the data being sent (operation 510). If the output of the peak detector circuit indicates the absence of data being sent, the process stores the current reference voltage as a voltage in a second number of voltages in a table (operation 512), with the process terminating thereafter. The second number of voltages is, for example, second number of voltages 128 in FIG. 1.

With reference again to operation 510, if the output of the peak detector circuit does not indicate the absence of data being sent, the process determines whether the current reference voltage is a highest voltage for the peak detector circuit (operation 514). If the current reference voltage is not the highest voltage, the process proceeds to operation 508 as described above. Otherwise, the process proceeds to operation 506 as described above.

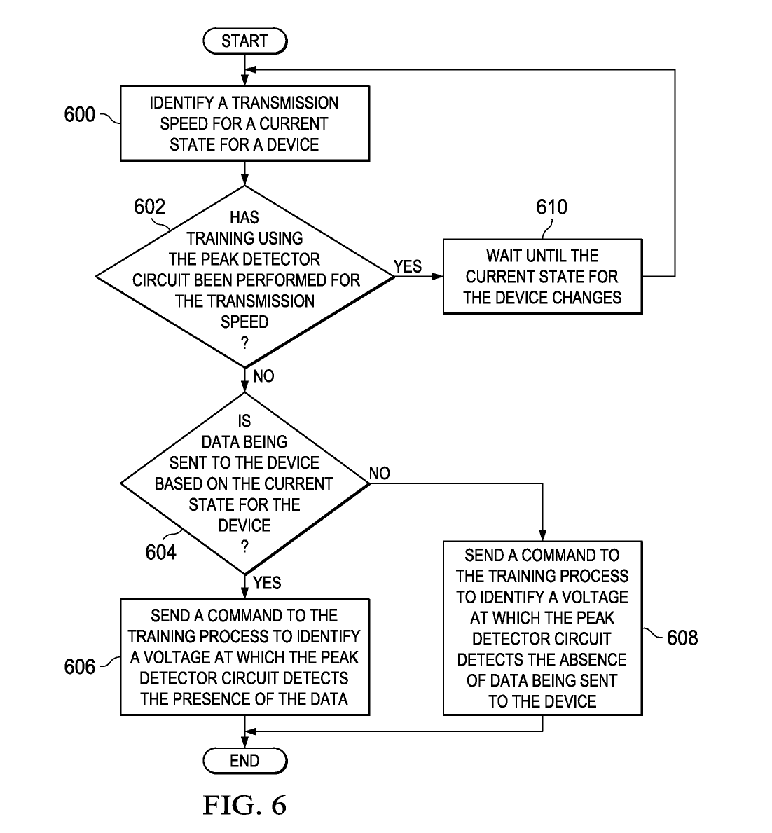

Turning now to FIG. 6, an illustration of a flowchart of a process for managing a training process is depicted in accordance with an illustrative embodiment. The process illustrated in FIG. 6 may be implemented using management process 214 in control module 208 in FIG. 2.

The process begins by identifying a transmission speed for a current state for a device (operation 600). The device comprises a peak detector circuit, a control module, and a multiplexer. Further, the device is connected to a bus system through a wire.

The process then determines whether training using the peak detector circuit has been performed for the transmission speed (operation 602). Training includes the identification of a first voltage in a first number of voltages and a second voltage in a second number of voltages for the transmission speed. When the peak detector circuit is set to the first voltage, the peak detector circuit detects a presence of data being sent to the device at the transmission speed. When the peak detector circuit is set to the second voltage, the peak detector circuit detects an absence of data being sent to the device at the transmission speed.

With reference again to operation 602, if training has not been performed for the transmission speed, the process determines whether data is being sent to the device based on the current state for the device (operation 604). If the process determines that data is being sent to the device in the current state for the device, the process sends a command to a training process to identify a voltage at which the peak detector circuit detects the presence of the data (operation 606), with the process terminating thereafter.

Otherwise, if the process determines that data is not being sent to the device in the current state for the device, the process sends a command to the training process to identify a voltage at which the peak detector circuit detects the absence of data being sent to the device (operation 608), with the process terminating thereafter.

With reference again to operation 602, if training has been performed for the transmission speed, the process waits until the current state for the device changes (operation 610), with the process proceeding to operation 600 as described above.

The flowcharts and block diagrams in the different depicted embodiments illustrate the architecture, functionality, and operation of some possible implementations of apparatus and methods in different illustrative embodiments. In this regard, each block in the flowcharts or block diagrams may represent a module, segment, function, and/or a portion of an operation or step. In some alternative implementations, the function or functions noted in the block may occur out of the order noted in the figures. For example, in some cases, two blocks shown in succession may be executed substantially concurrently, or the blocks may sometimes be executed in the reverse order, depending upon the functionality involved. Also, other blocks may be added in addition to the illustrated blocks in a flowchart or block diagram.

The description of the illustrative embodiments of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention and the practical application to enable others of ordinary skill in the art to understand the invention for various embodiments with various modifications as are suited to the particular use contemplated.

What is claimed is:

1. A method for managing peak detector circuits, the method comprising:
identifying a first number of voltages for a first number of signals detected by a peak detector circuit connected to a wire in a bus system, wherein the first number of signals is used to send data over the wire, and wherein the first number of voltages is for a first number of transmission speeds for the first number of signals;
identifying a second number of voltages for a second number of signals detected by the peak detector circuit, wherein the second number of signals is present in the wire in an absence of the data being sent over the wire, and wherein the second number of voltages is for a second number of transmission speeds for the second number of signals; and
selecting a number of settings for the peak detector circuit based on the first number of voltages and the second number of voltages.

2. The method of claim 1, wherein the step of identifying the first number of voltages for the first number of signals detected by the peak detector circuit comprises:
selecting a highest voltage as a current reference voltage for the peak detector circuit;
determining whether an output of the peak detector circuit indicates a presence of the data being sent over the wire in a signal in the first number of signals with the peak detector circuit set to the highest voltage; and
responsive to a determination that the output of the peak detector circuit indicates the presence of the data, selecting the current reference voltage for the peak detector circuit as a voltage in the first number of voltages.

3. The method of claim 2, wherein the step of identifying the first number of voltages for the first number of signals detected by the peak detector circuit further comprises:
responsive to an absence of the determination that the output of the peak detector circuit indicates the presence of the data, reducing the current reference voltage for the peak detector circuit;
determining whether the output of the peak detector circuit indicates the presence of the data being sent over the wire in the signal in the first number of signals after reducing the current reference voltage for the peak detector circuit; and
responsive to the determination that the output of the peak detector circuit indicates the presence of the data after reducing the current reference voltage, selecting the current reference voltage for the peak detector circuit as the voltage in the first number of voltages.

4. The method of claim 1, wherein the step of identifying the second number of voltages for the second number of signals detected by the peak detector circuit comprises:
selecting a lowest voltage as a current reference voltage for the peak detector circuit;
determining whether an output of the peak detector circuit indicates a presence of the data being sent over the wire in a signal in the first number of signals with the peak detector circuit set to the lowest voltage; and
responsive to an absence of a determination that the output of the peak detector circuit indicates the presence of the data, selecting the current reference voltage for the peak detector circuit as a voltage in the second number of voltages.

5. The method of claim 4, wherein the step of identifying the second number of voltages for the second number of signals detected by the peak detector circuit further comprises:
responsive to the determination that the output of the peak detector circuit indicates the presence of the data, increasing the current reference voltage for the peak detector circuit;
determining whether the output of the peak detector circuit indicates the presence of the data being sent over the wire in the signal in the first number of signals after increasing the current reference voltage for the peak detector circuit; and
responsive to the absence of the determination that the output of the peak detector circuit indicates the presence of the data after increasing the current reference voltage, selecting the current reference voltage for the peak detector circuit as the voltage in the second number of voltages.

6. The method of claim 1, wherein the step of selecting the number of settings for the peak detector circuit based on the first number of voltages and the second number of voltages comprises:
selecting a voltage in a range of voltages from a first voltage in the first number of voltages to a second voltage in the second number of voltages as a current reference voltage for the peak detector circuit, wherein both the first voltage and the second voltage correspond to a particular transmission speed.

7. The method of claim 1, wherein the peak detector circuit is associated with a device connected to the wire in the bus system and further comprising:
identifying a reference voltage for the peak detector circuit for a sleep state for the device, wherein the reference voltage is a voltage in a range of voltages from a first voltage in the first number of voltages to a second voltage in the second number of voltages as a current reference voltage for the peak detector circuit, wherein both the first voltage and the second voltage correspond to a particular transmission speed; and
setting the reference voltage for the peak detector circuit prior to the device going into the sleep state such that the peak detector circuit detects a presence of the data being sent over the wire in the bus system when the device changes from the sleep state to a working state.

8. The method of claim 1, wherein the peak detector circuit is associated with a device connected to the wire in the bus system and further comprising:
receiving a request for the device to change from a working state to a sleep state for the device;
identifying a transmission speed for the device for when the device changes from the sleep state to the working state;
identifying a first voltage in the first number of voltages for the transmission speed;
identifying a second voltage in the second number of voltages for the transmission speed;
setting a voltage in a range of voltages from the first voltage to the second voltage in the second number of voltages as a current reference voltage for the peak detector circuit; and
changing the working state to the sleep state for the device.

9. The method of claim 1 further comprising:
storing the first number of voltages for the first number of transmission speeds and the second number of voltages for the second number of transmission speeds in a table.

10. The method of claim 1, wherein the steps of identifying the first number of voltages for the first number of signals detected by the peak detector circuit connected to the wire in the bus system, wherein the first number of signals is used to send the data over the wire, and wherein the first number of voltages is for the first number of transmission speeds for the first number of signals; identifying the second number of voltages for the second number of signals detected by the peak detector circuit, wherein the second number of signals is present in the wire in the absence of the data being sent over the wire, and wherein the second number of voltages is for the second number of transmission speeds for the second number of signals; and selecting the number of settings for the peak detector circuit based on the first number of voltages and the second number of voltages are performed for each peak detector circuit connected to each wire in the bus system.

11. An apparatus comprising:
a bus system;
a peak detector circuit connected to a wire in the bus system; and
a control module associated with the peak detector circuit, wherein the control module is configured to identify a first number of voltages for a first number of signals detected by the peak detector circuit, wherein the first number of signals is used to send data over the wire, and wherein the first number of voltages is for a first number of transmission speeds for the first number of signals; identify a second number of voltages for a second number of signals detected by the peak detector circuit, wherein the second number of signals is present in an absence of the data being sent over the wire, and wherein the second number of voltages is for a second number of transmission speeds for the second number of signals; and select a number of settings for the peak detector circuit based on the first number of voltages and the second number of voltages.

12. The apparatus of claim 11, wherein in being configured to identify the first number of voltages for the first number of signals detected by the peak detector circuit, the control module is configured to select a highest voltage as a current reference voltage for the peak detector circuit; determine whether an output of the peak detector circuit indicates a presence of the data being sent over the wire in a signal in the first number of signals with the peak detector circuit set to the highest voltage; and select the current reference voltage for the peak detector circuit as a voltage in the first number of voltages in response to a determination that the output of the peak detector circuit indicates the presence of the data.

13. The apparatus of claim 12, wherein in being configured to identify the first number of voltages for the first number of signals detected by the peak detector circuit, the control module is further configured to reduce the current reference voltage for the peak detector circuit in response to an absence of the determination that the output of the peak detector circuit indicates the presence of the data; determine whether the output of the peak detector circuit indicates the presence of the data being sent over the wire in the signal in the first number of signals after reducing the current reference voltage for the peak detector circuit; and select the current reference voltage for the peak detector circuit as the voltage in the first number of voltages in response to the determination that the output of the peak detector circuit indicates the presence of the data after reducing the current reference voltage.

14. The apparatus of claim 11, wherein in being configured to identify the second number of voltages for the second number of signals detected by the peak detector circuit, the control module is configured to select a lowest voltage as a current reference voltage for the peak detector circuit; determine whether an output of the peak detector circuit indicates a presence of the data being sent over the wire in a signal in the first number of signals with the peak detector circuit set to the lowest voltage; and select the current reference voltage for the peak detector circuit as a voltage in the second number of voltages in response to an absence of a determination that the output of the peak detector circuit indicates the presence of the data.

15. The apparatus of claim 14, wherein in being configured to identify the second number of voltages for the second number of signals detected by the peak detector circuit, the control module is further configured to increase the current reference voltage for the peak detector circuit in response to the determination that the output of the peak detector circuit indicates the presence of the data; determine whether the output of the peak detector circuit indicates the presence of the data being sent over the wire in the signal in the first number of signals after increasing the current reference voltage for the peak detector circuit; and select the current reference voltage for the peak detector circuit as the voltage in the second number of voltages in response to the absence of the determination that the output of the peak detector circuit indicates the presence of the data after increasing the current reference voltage.

16. The apparatus of claim 11, wherein in being configured to select the number of settings for the peak detector circuit based on the first number of voltages and the second number of voltages, the control module is configured to select a voltage in a range of voltages from a first voltage in the first number of voltages to a second voltage in the second number of voltages as a current reference voltage for the peak detector circuit, wherein both the first voltage and the second voltage correspond to a particular transmission speed.

17. The apparatus of claim 11, wherein the peak detector circuit and the control module are associated with a device connected to the wire in the bus system and wherein the control module is further configured to identify a reference voltage for the peak detector circuit for a sleep state for the device in which the reference voltage is a voltage in a range of voltages from a first voltage in the first number of voltages to a second voltage in the second number of voltages as a current reference voltage for the peak detector circuit, wherein both the first voltage and the second voltage correspond to a particular transmission speed; and set the reference voltage for the peak detector circuit prior to the device going into a sleep state such that the peak detector circuit detects a presence of the data being sent over the wire in the bus system when the device changes from the sleep state to a working state.

18. The apparatus of claim 11, wherein the peak detector circuit and the control module are associated with a device connected to the wire in the bus system and wherein the control module is further configured to receive a request for the device to change from a working state to a sleep state; identify a transmission speed for the device when the device changes from the sleep state to the working state; identify a first voltage in the first number of voltages for the transmission speed; identify a second voltage in the second number of voltages for the transmission speed; and set a voltage in a range of voltages from the first voltage to the second voltage in the second number of voltages as a current reference voltage for the peak detector circuit.

19. The apparatus of claim 11, wherein the control module is further configured to store the first number of voltages for the first number of transmission speeds and the second number of voltages for the second number of transmission speeds in a table.

20. The apparatus of claim 11, wherein the control module is configured to perform the steps of identifying the first number of voltages for the first number of signals detected by the peak detector circuit connected to the wire in the bus system, wherein the first number of signals is used to send the data over the wire, and wherein the first number of voltages is for the first number of transmission speeds for the first number of signals; identifying the second number of voltages for the second number of signals detected by the peak detector circuit, wherein the second number of signals is present in the absence of the data being sent over the wire, and wherein the second number of voltages is for the second number of transmission speeds for the second number of signals; and selecting the number of settings for the peak detector circuit based on the first number of voltages and the second number of voltages for each peak detector connected to each wire in the bus system.
